(19) United States
(12) Patent Application Publication
(10) Pub. No.: US 2025/0228084 A1
(43) Pub. Date: Jul. 10, 2025

(54) ARRAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Junxiu Dai, Beijing (CN); Yuanqi Zhang, Beijing (CN); Yang Zeng, Beijing (CN); Chang Luo, Beijing (CN); Siyu Wang, Beijing (CN); Wei Wang, Beijing (CN); Tianci Chen, Beijing (CN); Yang Zhou, Beijing (CN); Lu Bai, Beijing (CN); Yi Qu, Beijing (CN); Song Liu, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/689,415

(22) PCT Filed: May 4, 2023
(86) PCT No.: PCT/CN2023/091995

§ 371 Date: Mar. 5, 2024

(51) Int. Cl. H10K 59/131; H10K 59/122; H10K 59/80

(52) U.S. Cl. CPC H10K 59/131; H10K 59/122; H10K 59/873

(57) ABSTRACT

An array substrate is provided. The array substrate includes one or more barrier walls and a plurality of signal lines in a peripheral area and on a side of the one or more barrier walls away from a base substrate. The peripheral area includes an inner region, an outer region, and one or more inter-barrier regions. The inner region is between a display area and a barrier wall closest to the display area. A respective one of the one or more inter-barrier regions is between two adjacent barrier walls. The outer region is on a side of a barrier wall most distal to the display area away from the display area. The plurality of signal lines include one or more first signal lines extending in at least one of the one or more inter-barrier region along a direction substantially parallel to at least one barrier wall.

### TECHNICAL FIELD

The present invention relates to display technology, more particularly, to an array substrate and a display apparatus.

### BACKGROUND

Organic light emitting diode (OLED) display apparatuses are self-emissive devices, and do not require backlights. OLED display apparatuses also provide more vivid colors and a larger color gamut as compared to the conventional liquid crystal display (LCD) apparatuses. Further, OLED display apparatuses can be made more flexible, thinner, and lighter than a typical LCD apparatus. An OLED display apparatus typically includes an anode, an organic layer including a light emitting layer, and a cathode. OLEDs can be either a bottom-emission type OLED or a top-emission type OLED.

### SUMMARY

In one aspect, the present disclosure provides an array substrate, comprising one of more barrier walls and a plurality of signal lines in a peripheral area and on a side of the one or more barrier walls away from a base substrate; wherein the peripheral area comprises an inner region, an outer region, and one or more inter-barrier regions; the inner region is between a display area and a barrier wall closest to the display area; a respective one of the one or more inter-barrier regions is between two adjacent barrier walls; the outer region is on a side of a barrier wall most distal to the display area away from the display area; and the plurality of signal lines comprise one or more first signal lines extending in at least one of the one or more inter-barrier region along a direction substantially parallel to at least one barrier wall.

Optionally, a respective first signal line of the one or more first signal lines comprises a first portion and a second portion connected to each other; the first portion extends in at least one of the one or more inter-barrier regions along a direction substantially parallel to at least one barrier wall; and the second portion crosses over at least one barrier wall.

Optionally, a length of the first portion extending in the at least one of the one or more inter-barrier region is at least 1.5 times of a respective inter-barrier distance of a respective inter-barrier region of the one or more inter-barrier regions.

Optionally, an orthographic projection of the first portion on the base substrate is substantially non-overlapping with an orthographic projection of any barrier wall on the base substrate; and an orthographic projection of the second portion on the base substrate at least partially overlaps with an orthographic projection of at least one barrier wall on the base substrate.

Optionally, the plurality of signal lines further comprise a plurality of second signal lines extending at least partially in the inner region, and at least partially crossing over the one or more inter-barrier regions; and a portion of a respective second signal line of the plurality of second signal lines in a respective inter-barrier region of the one or more inter-barrier regions extends along a direction non-parallel to the one or more barrier walls.

Optionally, a total length of the portion of the respective second signal line of the plurality of second signal lines in the respective inter-barrier region is in a range of 1.0 time to 1.5 times of a respective inter-barrier distance of a respective inter-barrier region of the one or more inter-barrier region.

Optionally, a respective second signal line of the plurality of second signal lines comprises a third portion and a fourth portion connected to each other; the third portion extends in the inner region along a direction substantially parallel to at least one barrier wall; and the fourth portion crosses over at least one barrier wall.

Optionally, the plurality of signal lines further comprise a plurality of third signal lines extending in the outer region; a respective third signal line of the plurality of third signal lines comprises a fifth portion and a sixth portion connected to each other; the fifth portion extends along a direction substantially parallel to at least one barrier wall; and the sixth portion extends along a direction non-parallel to the one or more barrier walls.

Optionally, in a region transitioning from a side region to a corner region of the peripheral area in a bottom bezel, the plurality of signal lines have a stepped pattern; and a respective signal line comprises first line segments and second line segments alternately connected together, the first line segments and the second line segments extending along different directions, and the second line segments extending toward the display area.

Optionally, the first line segments have a first average line width, the second line segments have a second average line width, the second average line width is greater than the first average line width; and the first line segments are spaced apart from each other by a first inter-segment distance, the second line segments are spaced apart from each other by a second inter-segment distance, the second inter-segment distance is greater than the first inter-segment distance.

Optionally, the array substrate further comprises a pixel definition layer in the display area; wherein the pixel definition layer is at least partially absent in the peripheral area; and the plurality of signal lines is spaced apart from an edge of the pixel definition layer by a distance no more than 100 μm.

Optionally, the peripheral area comprises a corner region; the corner region comprises a first sub-region in which a pixel definition layer is present, and a second sub-region in which layers comprising an organic material are removed; the array substrate comprises a plurality of apertures arranged in a grid-like pattern and extending through the pixel definition layer in the first sub-region; the first sub-region is spaced apart from the barrier walls by the second sub-region; and the second sub-region is substantially free of the plurality of signal lines.

Optionally, the one or more barrier walls comprise two adjacent barrier walls; the array substrate further comprises a groove spacing apart the two adjacent barrier walls; and one of more signal lines are present in an inter-barrier region corresponding to a groove where a width of the groove between the two adjacent barrier walls is greater than a sum of wall widths of two barrier walls adjacent to the groove.

Optionally, the array substrate further comprises an organic material layer adjacent to a barrier wall, and a groove spacing apart the organic material layer and the barrier wall; wherein one or more signal lines are present in a region corresponding to the groove where a width between the barrier wall and the organic material layer is greater than twice of a wall width of the barrier wall.

Optionally, the one or more barrier walls comprise a first adjacent barrier wall and a second adjacent barrier wall; wherein the array substrate further comprises a respective groove in an inter-barrier region between the first adjacent barrier wall and the second adjacent barrier wall; and a plurality of adjacent signal lines in the inter-barrier region corresponding to the respective groove; and wherein the plurality of adjacent signal lines in the inter-barrier region corresponding to the respective groove are alternately in two different layers.

Optionally, a portion of a respective adjacent signal line of the plurality of adjacent signal lines on a side of an adjacent barrier wall away from the respective groove comprises a double-layer portion having a first segment in a first conductive layer and a second segment in a second conductive layer, and the double-layer portion is connected to a portion of the respective adjacent signal line in the inter-barrier region corresponding to the respective groove.

Optionally, a respective adjacent signal line of the plurality of adjacent signal lines comprises at least a first single segment in a first conductive layer but absent in a second conductive layer, and a second single segment in the second conductive layer but absent in the first conductive layer; and in the inter-barrier region corresponding to the respective groove, one or more first single segments and one or more second single segments respectively from adjacent signal lines are alternately arranged.

Optionally, a total length of first single segment(s) and a total length of second single segment(s) in the respective adjacent signal line are substantially the same; and the plurality of signal lines have a substantially the same total lengths of single segments.

Optionally, first single segment(s) and second single segment(s) of a same respective signal line are in different regions of the peripheral area on different sides of the display area, respectively.

In another aspect, the present disclosure provides a display apparatus, comprising the array substrate described herein, and one or more integrated circuits connected to the array substrate; wherein the display apparatus comprises a plurality of light emitting elements on the base substrate; an encapsulating layer on a side of the plurality of light emitting elements away from the base substrate; a first touch metal layer on a side of the encapsulating layer away from the base substrate; a touch insulating layer on a side of the first touch metal layer away from the base substrate; and a second touch metal layer on a side of the touch insulating layer away from the base substrate; wherein the plurality of signal lines are a plurality of touch control signal lines in at least one of the first touch metal layer or the second touch metal layer.

In another aspect, the present disclosure provides an array substrate, comprising a display area and a peripheral area; wherein the array substrate in the peripheral area comprises a first organic structure, one or more barrier walls, and a second organic structure sequentially arranged along a direction away from the display area; wherein a respective barrier wall of the one or more barrier walls comprises one or more organic insulating layers; wherein the respective barrier wall spaces apart two adjacent grooves extending at least partially into the one or more organic insulating layers; and the two adjacent grooves are on two sides of the respective barrier wall along the direction along which the first organic structure, the one or more barrier walls, and the second organic structure are sequentially arranged; wherein the array substrate further comprises a plurality of signal lines in the peripheral area and on a side of the one or more barrier walls away from a base substrate; and at least one signal line of the plurality of signal lines extends along a direction substantially parallel to the one or more barrier walls in a region having a groove adjacent to a barrier wall.

Optionally, the one or more barrier walls comprise two adjacent barrier walls; the array substrate further comprises a groove spacing apart the two adjacent barrier walls; and one or more signal lines are present in an inter-barrier region corresponding to a groove where a width of the groove between the two adjacent barrier walls is greater than a sum of wall widths of two barrier walls adjacent to the groove.

Optionally, the array substrate further comprises an organic structure adjacent to a barrier wall, and a groove spacing apart the organic structure and the barrier wall; wherein one or more signal lines are present in a region corresponding to the groove where a width between the barrier wall and the organic structure is greater than twice of a wall width of the barrier wall.

Optionally, a groove is adjacent to a barrier wall or an organic structure having a slope angle in a range of 5 degrees to 30 degrees; a width of the groove, when the groove is between the adjacent barrier walls, is equal to or less than a sum of wall widths of the two adjacent barrier walls, or, when the groove is between a barrier wall and an organic structure, is equal to or less than twice of a wall width of the barrier wall; and at least one signal line of the plurality of signal lines extends along a direction substantially parallel to the one or more barrier walls in a region having the groove adjacent to the barrier wall or the organic structure having the slope angle in the range of 5 degrees to 30 degrees.

Optionally, a groove is adjacent to a barrier wall or an organic structure having a thickness in a range of 1 μm to 2 μm; a width of the groove, when the groove is between two adjacent barrier walls, is equal to or less than a sum of wall widths of the two adjacent barrier walls, or, when the groove is between a barrier wall and an organic structure, is equal to or less than twice of a wall width of the barrier wall; and at least one signal line of the plurality of signal lines extends along a direction substantially parallel to the one or more barrier walls in a region having the groove adjacent to the barrier wall or the organic structure having the thickness in the range of 1 μm to 2 μm.

Optionally, a groove is adjacent to a barrier wall or an organic structure having a slope angle greater than 30 degrees or having a thickness greater than 2 μm; a width of the groove, when the groove is between two adjacent barrier walls, is equal to or less than a sum of wall widths of the two adjacent barrier walls, or, when the groove is between a barrier wall and an organic structure, is equal to or less than twice of a wall width of the barrier wall; and none of the plurality of signal lines extends along a direction substantially parallel to the one or more barrier walls in a region having the groove adjacent to the barrier wall or the organic structure having the slope angle greater than 30 degrees or having the thickness greater than 2 μm.

### BRIEF DESCRIPTION OF THE FIGURES

The following drawings are merely examples for illustrative purposes according to various disclosed embodiments and are not intended to limit the scope of the present invention.

FIG. 1 illustrates a detailed structure in a display area in a display apparatus in some embodiments according to the present disclosure.

FIG. 2 illustrates a detailed structure in a display area in a display apparatus in some embodiments according to the present disclosure.

FIG. 3 is a diagram illustrating a layout of certain signal lines in an array substrate in some embodiments according to the present disclosure.

FIG. 4 illustrates a layout of signal lines in an array substrate in some embodiments according to the present disclosure.

FIG. 5A illustrates a layout of signal lines in a portion of an array substrate in some embodiments according to the present disclosure.

FIG. 5B illustrates a layout of a plurality of first data lines in the portion of the array substrate depicted in FIG. 5A.

FIG. 5C illustrates a layout of a plurality of second data lines, a plurality of first fanout connecting lines, and a plurality of second fanout connecting lines in the portion of the array substrate depicted in FIG. 5A.

FIG. 5D illustrates a layout of signal lines not involved in data signal transmission in the portion of the array substrate depicted in FIG. 5A.

FIG. 6 illustrates a layout of signal lines not involved in data signal transmission in the array substrate depicted in FIG. 4,

FIG. 7 is a schematic diagram illustrating the structure of a portion of an array substrate in some embodiments according to the present disclosure.

FIG. 8 is a plan view of an array substrate in some embodiments according to the present disclosure.

FIG. 9 is a schematic diagram illustrating a display area and a peripheral area in an array substrate in some embodiments according to the present disclosure.

FIG. 10 is a diagram illustrating a layout of signal lines in a peripheral area in a related array substrate.

FIG. 11 is a diagram illustrating a layout of signal lines in a peripheral area in a related array substrate.

FIG. 12 is a diagram illustrating a layout of signal lines in a peripheral area in an array substrate in some embodiments according to the present disclosure.

FIG. 13A is a diagram illustrating a layout of signal lines in a peripheral area in an array substrate in some embodiments according to the present disclosure.

FIG. 13B is a diagram illustrating a layout of first line segments and second line segments in some embodiments according to the present disclosure.

FIG. 13C is a cross-sectional view along an A-A′ line in FIG. 13A.

FIG. 14 is a diagram illustrating a layout of signal lines in a peripheral area in an array substrate in some embodiments according to the present disclosure.

FIG. 15 is a cross-sectional view of a portion of an array substrate in some embodiments according to the present disclosure.

FIG. 16 is a cross-sectional view of a portion of an array substrate in some embodiments according to the present disclosure.

FIG. 17 is a cross-sectional view of a portion of an array substrate in some embodiments according to the present disclosure.

FIG. 18A is a diagram illustrating a layout of signal lines in an inter-barrier region in an array substrate in some embodiments according to the present disclosure.

FIG. 18B is a cross-sectional view along a B-B′ line in FIG. 18A.

FIG. 19 is a diagram illustrating a layout of signal lines in an inter-barrier region in an array substrate in some embodiments according to the present disclosure.

FIG. 20 is a diagram illustrating a layout of signal lines in an inter-barrier region in an array substrate in some embodiments according to the present disclosure.

FIG. 21 is a diagram illustrating the structure of an array substrate in some embodiments according to the present disclosure.

FIG. 22 is a diagram illustrating a layout of signal lines in a first zoom-in region in the array substrate depicted in FIG. 21.

FIG. 23 is a diagram illustrating a layout of signal lines in a second zoom-in region in the array substrate depicted in FIG. 21.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

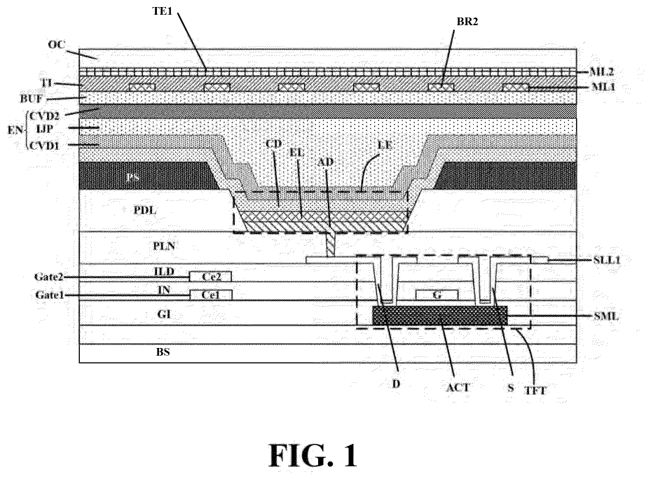

FIG. 1 illustrates a detailed structure in a display area in a display apparatus in some embodiments according to the present disclosure. Referring to FIG. 1, the display apparatus in the display area in some embodiments includes a base substrate BS (e.g., a flexible base substrate); an active layer ACT of a respective one of a plurality of thin film transistors TFT on the base substrate BS; a gate insulating layer GI on a side of the active layer ACT away from the base substrate BS; a gate electrode O and a first capacitor electrode Ce1 (both are parts of a first gate metal layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second gate metal layer) on a side of the insulating layer IN away from the gate insulating layer GI, an inter-layer dielectric layer ILD on a side of the second capacitor electrode Ce2 away from the gate Insulating layer GI, a source electrode S and a drain electrode D (parts of a first SD metal layer) on a side of the inter-layer dielectric layer ILD away from the gate insulating layer GI; a planarization layer PLN on a side of the source electrode S and the drain electrode D away from the inter-layer dielectric layer ILD; a pixel definition layer PDL defining a subpixel aperture and on a side of the planarization layer PLN away from the base substrate BS; and a light emitting element LE in the subpixel aperture. The light emitting element LE includes an anode AD on a side of the planarization layer PLN away from the inter-layer dielectric layer ILD; a light emitting layer EL on a side of the anode AD away from the planarization layer PLN; and a cathode layer CD on a side of the light emitting layer EL away from the anode AD. The display apparatus in the display area further includes an encapsulating layer EN encapsulating the dummy light emitting element DLE, and on a side of the cathode layer CD away from the base substrate BS. The encapsulating layer EN in some embodiments includes a first inorganic encapsulating sub-layer CVD1 on a side of the cathode layer CD away from the base substrate BS, an organic encapsulating sub-layer IJP on a side of the first inorganic encapsulating sub-layer CVD1 away from the base substrate BS, and a second inorganic encapsulating sub-layer CVD2 on a side of the organic encapsulating sub-layer IJP away from the first inorganic encapsulating sub-layer CVD1. The display apparatus in the display area further includes a buffer layer BUF on a side of the encapsulating layer EN away from the base substrate BS; a plurality of second electrode bridges BR2 on a side of the buffer layer BUF away from the encapsulating layer EN; a touch insulating layer TI on a side of the plurality of second electrode bridges BR2 away from the buffer layer BUF; a plurality of first touch electrodes TE1 on a side of the touch insulating layer TI away from the buffer layer BUF; and an overcoat layer OC on a side of the plurality of first touch electrodes TE1 away from the touch insulating layer TI.

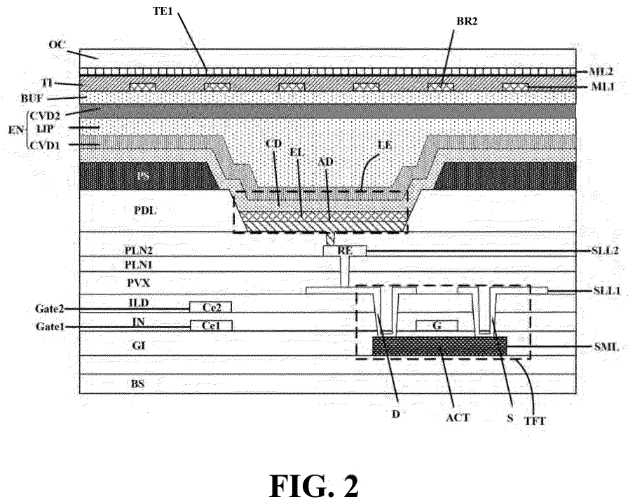

FIG. 2 illustrates a detailed structure in a display area in a display apparatus in some embodiments according to the present disclosure. Referring to FIG. 2, the display apparatus in the display area in some embodiments includes a base substrate BS (e.g., a flexible base substrate); an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first gate metal layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second gate metal layer) on a side of the insulating layer IN away from the gate insulating layer GI; an inter-layer dielectric layer ILD on a side of the second capacitor electrode Ce2 away from the gate insulating layer GI; a source electrode S and a drain electrode D (parts of a first SD metal layer) on a side of the inter-layer dielectric layer ILD away from the gate insulating layer GI; a passivation layer PVX on a side of the source electrode S and the drain electrode D away from the inter-layer dielectric layer ILD; a first planarization layer PLN1 on a side of the passivation, layer PVX away from the inter-layer dielectric layer ILD; a relay electrode RE (part of a second SD metal layer) on a side of the first planarization layer PLN1 away from the passivation layer PVX; a second planarization layer PLN2 on a side of the relay electrode RE away from the first, planarization layer PLN1; a pixel definition layer PDL defining a subpixel aperture and on a side of the second planarization layer PLN2 away from the base substrate BS; and a light emitting element LE in the subpixel aperture. The light emitting element LE includes an anode AD on a side of the second planarization layer PLN2 away from the first planarization layer PLN1; a light, emitting layer EL on a side of the anode AD away from the second planarization layer PLN2; and a cathode layer CD on a side of the light emitting layer EL away from the anode AD. The display apparatus in the display area further includes an encapsulating layer EN encapsulating the dummy light emitting element DLE, and on a side of the cathode layer CD away from the base substrate BS. The encapsulating layer EN in some embodiments includes a first inorganic encapsulating sub-layer CVD1 on a side of the cathode layer CD away from the base substrate BS, an organic encapsulating sub-layer IJP on a side of the first inorganic encapsulating sub-layer CVD1 away from the base substrate BS, and a second inorganic encapsulating sub-layer CVD2 on a side of the organic encapsulating sub-layer IJP away from the first inorganic encapsulating sub-layer CVD1. The display apparatus in the display area further includes a buffer layer BUF on a side of the encapsulating layer EN away from the base substrate BS; a plurality of second electrode bridges BR2 on a side of the buffer layer BUF away from the encapsulating layer EN; a touch insulating layer TI on a side of the plurality of second electrode bridges BR2 away from the buffer layer BUF; a plurality of first touch electrodes TE1 on a side of the touch insulating layer TI away from the buffer layer BUF; and an overcoat layer OC on a side of the plurality of first touch electrodes TE1 away from the touch insulating layer TI. Optionally, the display apparatus in the display area does not include the passivation layer PVX. e.g., the inter-layer dielectric layer ILD is in direct contact with the first planarization layer PLN1.

Referring to FIG. 1 and FIG. 2, the display apparatus includes a semiconductor material layer SML, a first gate metal layer Gate1, a second gate metal layer Gate2, a first signal line layer SLL1, and a second signal line layer SLL2. The display apparatus further includes an insulating layer IN between the first gate metal layer Gate1 and the second gate metal layer Gate2; an inter-layer dielectric layer ILD between the second gate metal layer Gate2 and the first signal line layer SLL1; and at least a passivation layer PVX or a planarization layer PLN between the first signal line layer SLL1 and the second signal line layer SLL2. Optionally, the plurality of second electrode bridges BR2 are in a first touch metal layer ML1, and the plurality of first touch electrodes TE1 are in a second touch metal layer ML2.

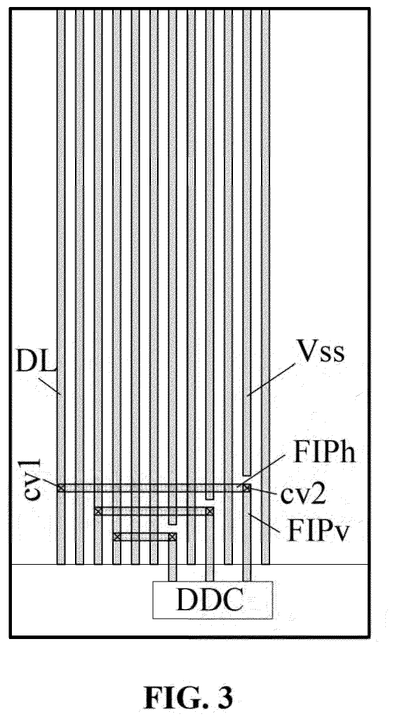

FIG. 3 is a diagram illustrating a layout of certain signal lines in an array substrate in some embodiments according to the present disclosure. Referring to FIG. 3, in some embodiments, the array substrate includes a plurality of data lines DL, a plurality of first fanout connecting lines FIPh, and a plurality of second fanout connecting lines FIPv. In some embodiments, an individual data line of the plurality of data lines DL is connected to a respective first fanout connecting line of the plurality of first fanout connecting lines FIPh, e.g., through a first connecting via cv1 extending through the second planarization layer. A respective second fanout connecting line of the plurality of second fanout connecting lines FIPv is connected to the respective first fanout connecting line of the plurality of first fanout connecting lines FIPh, e.g., through a second connecting via cv2 extending through the second planarization layer. The respective first fanout connecting line connects the respective data line DL with the respective second fanout connecting line. The plurality of second fanout connecting lines are connected to a data driving circuit DDC. Optionally, an individual first fanout connecting line of the plurality of first fanout connecting lines FIPh is connected to only one data line of the plurality of data lines DL, and an individual data line of the plurality of data lines DL is connected to only one first fanout connecting line of the plurality of first fanout connecting lines FIPh. Optionally, an individual second fanout connecting line of the plurality of second fanout connecting lines FIPv is connected to only one first fanout connecting line of the plurality of first fanout connecting lines FIPh, and an individual first fanout connecting line of the plurality of first fanout connecting lines FIPh is connected to only one second fanout connecting line of the plurality of second fanout connecting lines FIPv.

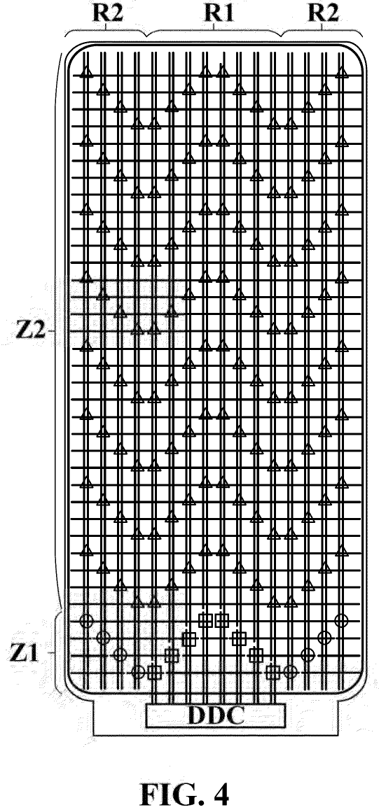

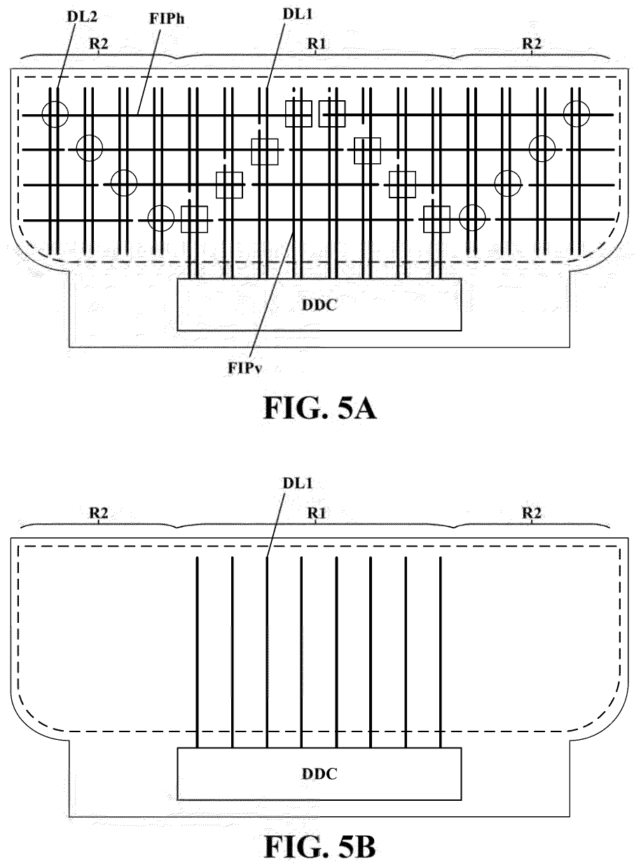

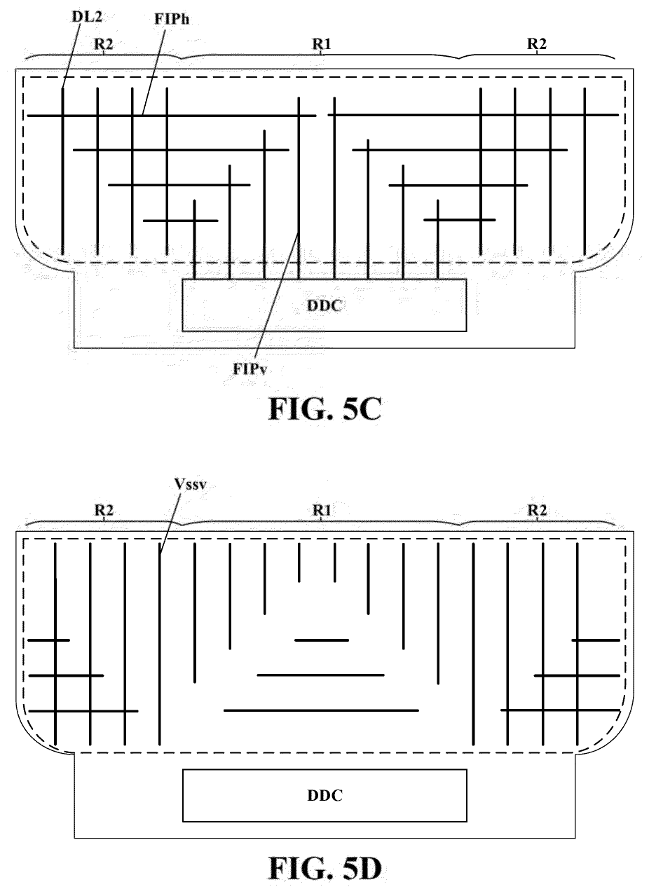

FIG. 4 illustrates a layout of signal lines in an array substrate in some embodiments according to the present disclosure. FIG. 5A illustrates a layout of signal lines in a portion of an array substrate in some embodiments according to the present disclosure. Referring to FIG. 4 and FIG. 5A, the array substrate in some embodiments includes a plurality of data lines, a plurality of first fanout connecting lines FIPh, and a plurality of second fanout connecting lines FIPv.

The array substrate includes a first region R1 and a second region R2 outside the first region R1. The first region R1 includes a plurality of first columns of subpixels, the second region R2 includes a plurality of second columns of subpixels. The plurality of first columns of subpixels are different from the plurality of second columns of subpixels. In some embodiments, the first region R1 and the second region R2 are in a display area of the array substrate. As used herein, the term “display area” refers to an area of an array substrate in a display panel where image is actually displayed. Optionally, the display area may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding to a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels.

FIG. 5B illustrates a layout of a plurality of first data lines in the portion of the array substrate depicted in FIG. 5A. FIG. 5C illustrates a layout of a plurality of second data lines, a plurality of first fanout connecting lines, and a plurality of second fanout connecting lines in the portion of the array substrate depicted in FIG. 5A. Referring to FIG. 4, FIG. 5A to FIG. 5C, the plurality of data lines includes a plurality of first data lines DL1 configured to provide data signals to the plurality of first columns of subpixels in the first region R1, and a plurality of second data lines DL2 configured to provide data signals to the plurality of second columns of subpixels in the second region R2.

In some embodiments, the plurality of first data lines DL1 are connected to the data driving circuit DDC; and the plurality of second data lines DL2 are connected to the data driving circuit DDC through the plurality of first fanout connecting lines FIPh and the plurality of second fanout connecting lines FIPv. Optionally, a respective second data line of the plurality of second data lines DL2 is connected to the data driving circuit DDC through a respective first fanout connecting line of the plurality of first fanout connecting lines FIPh and a respective second fanout connecting line of the plurality of second fanout connecting lines FIPv. The respective first fanout connecting line of the plurality of first fanout connecting lines FIPh and the respective second fanout connecting line of the plurality of second fanout connecting lines FIPv are connected to each other. The plurality of first fanout connecting lines FIPh and the plurality of second fanout connecting lines FIPv are substantially (e.g., at least 50%, at least 60%, at least 70%, at least 80%, at least 90%, at least 95%, at least 98%, at least 99%, or 100%) in the display area of the array substrate.

A circle mark in FIG. 4, FIG. 5A, and FIG. 5C denotes a connection between the respective first fanout connecting line of the plurality of first fanout connecting lines FIPh and the respective second data line of the plurality of second data lines DL2. A square mark in FIG. 4, FIG. 5A, and FIG. 5C denotes a connection between the respective first fanout connecting line of the plurality of first fanout connecting lines FIPh and the respective second fanout connecting line of the plurality of second fanout connecting lines FIPv. Optionally, the respective second data line of the plurality of second data lines DL2 is connected to the respective first fanout connecting line of the plurality of first fanout connecting lines FIPh through a via extending through the second planarization layer. Optionally, the respective second fanout connecting line of the plurality of second fanout connecting lines FIPv is connected to the respective first fanout connecting line of the plurality of first fanout connecting lines FIPh through a via extending through the second planarization layer.

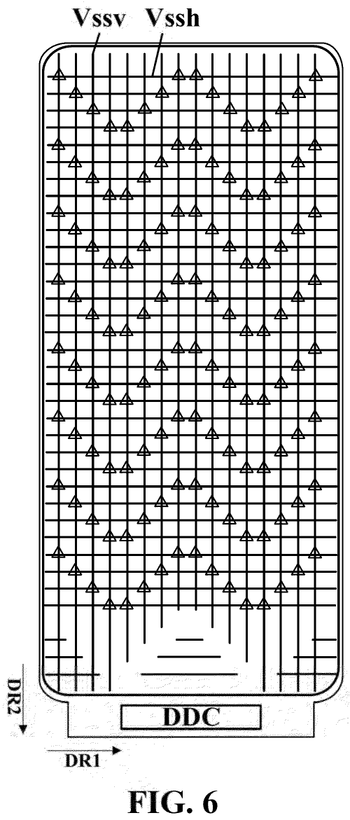

FIG. 5D illustrates a layout of signal lines not involved in data signal transmission in the portion of the array substrate depicted in FIG. 5A. FIG. 6 illustrates a layout of signal lines not involved in data signal transmission in the array substrate depicted in FIG. 4. Referring to FIG. 4, FIG. 5A, FIG. 5D, and FIG. 6, the array substrate in some embodiments further includes a plurality of second voltage supply lines Vssv and a plurality of third voltage supply lines Vssh. The plurality of second voltage supply lines Vssv extend along a direction substantially parallel to the second direction DR2. The plurality of third voltage supply lines Vssh extend along a direction substantially parallel to the first direction DR1.

In some embodiments, the plurality of first voltage supply lines are configured to provide a first reference voltage signal (e.g., a high reference voltage signal). The plurality of second voltage supply lines Vssv and the plurality of third voltage supply lines Vssh are configured to provide a second reference voltage signal (e.g., a low reference voltage signal). Optionally, the first reference voltage signal is a constant voltage signal, the second reference voltage signal is a constant voltage signal, the first reference voltage signal has a voltage level higher than a voltage level of the second reference voltage signal.

In some embodiments, the plurality of third voltage supply lines Vssh and the plurality of first fanout connecting lines FIPh are in a same layer; and the plurality of second voltage supply lines Vssv and the plurality of second fanout connecting lines FIPv are in a same layer. Optionally, the plurality of third voltage supply lines Vssh and the plurality of first fanout connecting lines FIPh are in the second signal line layer. Optionally, the plurality of second voltage supply lines Vssv and the plurality of second fanout connecting lines FIPv are in the third signal line layer.

In some embodiments, the plurality of second voltage supply lines Vssv and the plurality of third voltage supply lines Vssh form an interconnected voltage supply network. In some embodiments, a respective second voltage supply line of the plurality of second voltage supply lines Vssv is connected to one or more third voltage supply lines of the plurality of third voltage supply lines Vssh through one or more vias, e.g., one or more vias extending through the second planarization layer PLN2, The triangle mark in FIG. 4 and FIG. 6 denotes a connection between the respective second voltage supply line of the plurality of second voltage supply lines Vssv and the respective third voltage supply line of the plurality of third voltage supply lines Vssh.

In some embodiments, the array substrate includes a first zone Z1 and a second zone Z2 outside the first zone Z1. The first zone Z1 includes a plurality of first rows of subpixels, the second zone Z2 includes a plurality of second rows of subpixels. The plurality of first rows of subpixels are different from the plurality of second rows of subpixels. In some embodiments, the first zone Z1 and the second zone Z2 are in a display area of the array substrate.

In some embodiments, connections between the plurality of first fanout connecting lines FIPh and the plurality of second data lines DL2 (circle marks) and connections between the plurality of first fanout connecting lines FIPh and the plurality of second fanout connecting lines FIPv (square marks) are in the first zone Z1. In some embodiments, connections between the plurality of second voltage supply lines Vssv and the plurality of third voltage supply lines Vssh (triangle marks) are in the second zone Z2.

In some embodiments, the connections between the plurality of first fanout connecting lines FIPh and the plurality of second data lines DL2 (circle marks) and connections between the plurality of first fanout connecting lines FIPh and the plurality of second fanout connecting lines FIPv (square marks) in the first zone Z1 constitute a first group of connections. In some embodiments, the connections between the plurality of second voltage supply lines Vssv and the plurality of third voltage supply lines Vssh in the second zone Z2 include one or more second groups of connections between the plurality of second voltage supply lines Vssv and the plurality of third voltage supply lines Vssh. In some embodiments, a respective second group of the one or more second groups of connections in the second zone Z2 has a same pattern as the first group of connections in the first zone Z1. In some embodiments, the first group of connections and the one or more second groups of connections are distributed substantially evenly in the array substrate, e.g., along the second direction DR2.

The inventors of the present disclosure discover that, by having the one or more second groups of connections having a same pattern as the first group of connections, and by having the first group of connections and the one or more second groups of connections distributed substantially evenly in the array substrate, an enhanced display uniformity can be achieved.

In some embodiments, the interconnected voltage supply network comprising the plurality of second voltage supply lines Vssv and the plurality of third voltage supply lines Vssh is electrically connected to a peripheral voltage supply line to receive a second reference voltage signal. Optionally, the interconnected voltage supply network is electrically connected to a cathode of the light emitting elements in the array substrate, and functions as an auxiliary cathode.

In the realm of AMOLED smartphones, a prominent trend in recent development is the pursuit of narrow bezels, particularly achieving bezel sizes of 1.0 mm or even less on the left, right, and top edges of the screen. However, it remains relatively difficult to reduce the size of the bottom bezel, limiting the screen-to-body ratio. To address this, a new design approach called fanout connecting lines in display area has emerged, which allows for a significant reduction in the size of the bottom bezel. The fanout connecting lines depicted in FIG. 3 to FIG. 6 epitomizes the fanout connecting lines in display area technology.

In related array substrates, the fanout lines are disposed exclusively in the bottom bezel, and the fanout lines and touch signal lines in the bottom bezel takes up a significant amount of space. The inventors of the present disclosure discover that, by having the fanout connecting lines at least partially in the display area, the bezel sizes of the array substrate can be significantly reduced.

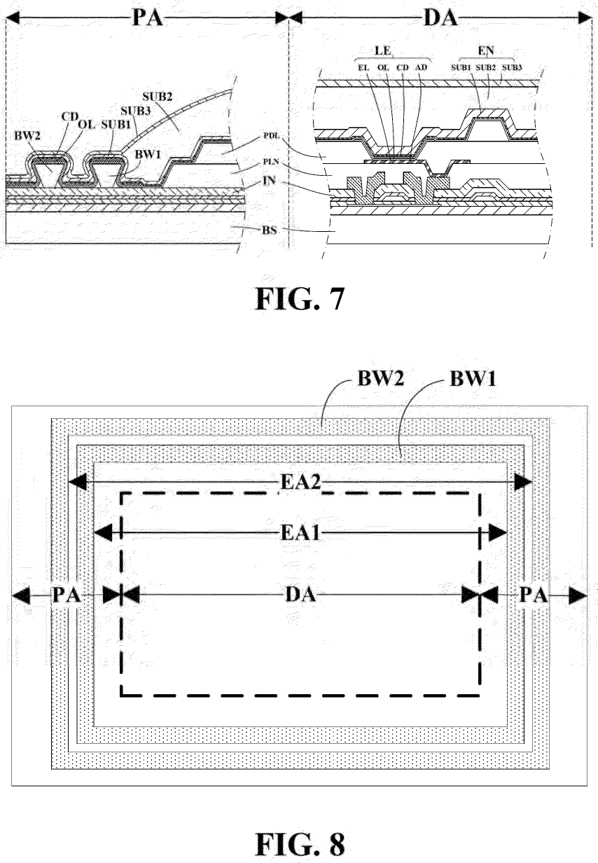

FIG. 7 is a schematic diagram illustrating the structure of a portion of an array substrate in some embodiments according to the present disclosure. FIG. 8 is a plan view of an array substrate in some embodiments according to the present disclosure. Referring to FIG. 7 and FIG. 8, the array substrate in some embodiments has a display area DA and a peripheral area PA. In some embodiments, the array substrate includes a base substrate BS: a plurality of light emitting elements LE on the base substrate BS and in the display area DA; an encapsulating layer EN on a side of the plurality of light emitting elements LE distal to the base substrate BS to encapsulate the plurality of light emitting elements LE; an insulating layer IN on the base substrate BS; a first barrier wall BW1 in the peripheral area PA and on a side of the insulating layer IN away from the base substrate BS, the first barrier wall BW1 forming a first enclosure substantially surrounding a first area EA1; and a second barrier wall BW2 in the peripheral area PA and on a side of the insulating layer IN away from the base substrate BS. The second barrier wall BW2 forms a second enclosure substantially surrounding a second area EA2. Optionally, the second area EA2 encloses the first area EA1.

As used herein the term “peripheral area” refers to an area of an array substrate in a display panel where various circuits and wires are provided to transmit signals to the display substrate. To increase the transparency of the display apparatus, non-transparent or opaque components of the display apparatus (e.g., battery, printed circuit board, metal frame), can be disposed in the peripheral area rather than in the display areas.

In some embodiments, the encapsulating layer EN includes a first inorganic encapsulating sub-layer SUB1, an organic encapsulating sub-layer SUB2, and a second inorganic encapsulating sub-layer SUB3. In some embodiments, at least one inorganic sub-layer of the encapsulating layer EN extends from the display area DA into the peripheral area PA. In one example, the first inorganic encapsulating sub-layer SUB1 and the second inorganic encapsulating sub-layer SUB3 extend from the display area DA into the peripheral area PA. Optionally, each of the first inorganic encapsulating sub-layer SUB1, the organic encapsulating sub-layer SUB2, and the second inorganic encapsulating sub-layer SUB3 extends from the display area DA into the peripheral area PA. Optionally, the at least one inorganic sub-layer of the encapsulating layer EN is on a side of the organic encapsulating sub-layer SUB2 away from the base substrate BS. Optionally, the at least one inorganic sub-layer of the encapsulating layer EN is on a side of the first barrier wall BW1 away from the base substrate BS.

A respective one of the plurality of light emitting elements LE includes an anode AD, a light emitting layer EL on the anode AD, the organic material layer OL on a side of the light emitting layer EL away from the base substrate BS, the cathode layer CD on a side of the organic material layer OL away from the base substrate BS. Optionally, the organic material layer OL and the cathode layer CD can be formed in an open mask process.

In some embodiments, the array substrate further includes a planarization layer PLN on a side of the plurality of thin film transistors away from the base substrate BS. The anode AD is electrically connected to the drain electrode D of the respective one of the plurality of thin film transistor through a via extending through the planarization layer PLN.

In some embodiments, the array substrate further includes a pixel definition layer PDL on a side of the planarization layer PLN away from the base substrate BS. The pixel definition layer PDL defines a plurality of subpixel apertures for receiving the light emitting layer EL.

Various appropriate materials may be used for making the first barrier wall BW1 and the second barrier wall BW2. In one example, the first barrier wall BW1 and the second barrier wall BW2 are made of an organic material. In another example, the first barrier wall BW1 and the second barrier wall BW2 are made of a same organic material as the organic encapsulating sub-layer SUB2 of the encapsulating layer EN. In another example, the first barrier wall BW1, the second barrier wall BW2, and the organic encapsulating sub-layer SUB2 are in a same layer. As used herein, the term “same layer” refers to the relationship between the layers simultaneously formed in the same step. In one example, the first barrier wall BW1 and the organic encapsulating sub-layer SUB2 are in a same layer when they are formed as a result of one or more steps of a same patterning process performed in a material deposited in a same deposition process. In another example, the first barrier wall BW1 and the organic encapsulating sub-layer SUB2 can be formed in a same layer by simultaneously performing the step of forming the first barrier wall BW1 and the step of forming the organic encapsulating sub-layer SUB2. The term “same layer” does not always mean that the thickness of the layer or the height of the layer in a cross-sectional view is the same.

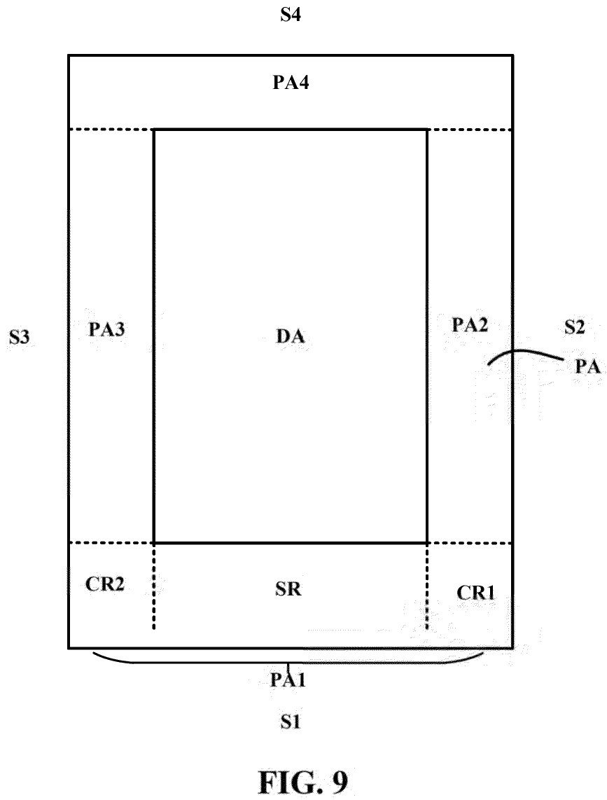

FIG. 9 is a schematic diagram illustrating a display area and a peripheral area in an array substrate in some embodiments according to the present disclosure. Referring to FIG. 9 in some embodiments, the peripheral area PA includes a first sub-area PA1 on a first side S1 of the display area DA, a second sub-area PA2 on a second side S2 of the display area DA, a third sub-area PA3 on a third side S3 of the display area DA, a fourth sub-area PA4 on a fourth side S4 of the display area DA. Optionally, the first side S1 and the fourth side S4 are opposite to each other. Optionally, the second side S2 and the third side S3 are opposite to each other. Optionally, the first sub-area PA1 is a sub-area where the plurality of signal lines are connected to an integrated circuit (e.g., an integrated touch control circuit).

In some embodiments, the first sub-area PA1 includes a side region SR and one or more corner regions (e.g., a first corner region CR1 and a second corner region CR2). The one or more corner regions are respectively at a corner of the array substrate. The one or more corner regions respectively connect the side region SR to one or more adjacent sub-areas of the peripheral area PA. For example, the first corner region CR1 connects the side region SR to the second sub-area PA2, and the second corner region CR2 connects the side region SR to the third sub-area PA3.

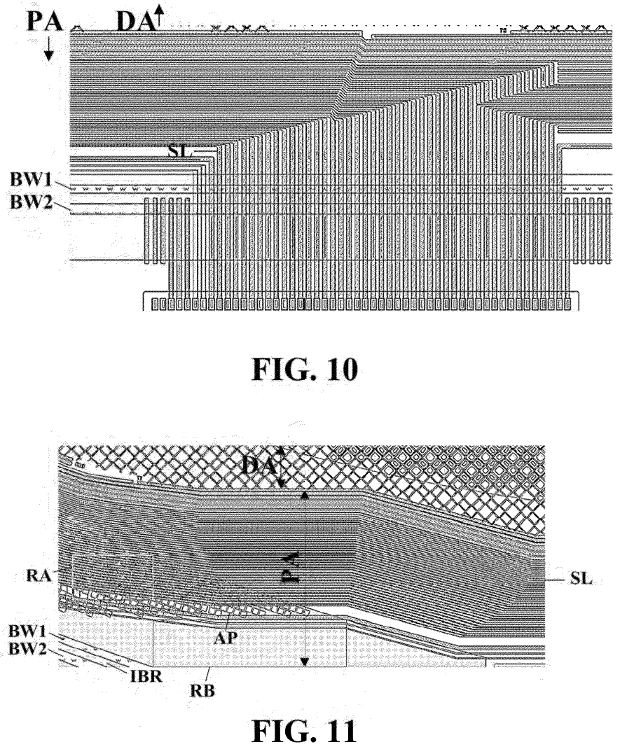

FIG. 10 is a diagram illustrating a layout of signal lines in a peripheral area in a related array substrate, Referring to FIG. 10, the related array substrate includes a plurality of signal lines SL (e.g., a plurality of touch signal lines) in a peripheral area PA of the related array substrate. FIG. 10 may depict the layout of the plurality of signal lines SL in the side region SR (in the bottom bezel region) depicted in FIG. 9.

In the related array substrate, the plurality of signal lines SL at least partially cross over barrier walls (including a first barrier wall BW1 and a second barrier wall BW2), In the related array substrate, fanout lines are typically disposed in the same area. However, in an array substrate having the fanout connecting lines in the display area DA, the signal line layout depicted in FIG. 10 is not suitable because the bottom bezel area is significantly reduced in the array substrate having the fanout connecting lines in the display area DA and thus does not have sufficient space for the plurality of signal lines SL.

FIG. 11 is a diagram illustrating a layout of signal lines in a peripheral area in a related, array substrate. FIG. 1l may depict the layout of the plurality of signal lines SL in a corner region (e.g., the first corner region CR1) depicted in FIG. 9. In this region, the layout of the plurality of signal lines SL is to ensure the integrity of the signal lines. The plurality of signal lines SL are disposed as close as possible to the barrier walls (e.g., the first barrier wall BW1). As shown in FIG. 11, in this region, the plurality of signal lines SL are between the first barrier wall BW1 and the display area DA, wherein the first barrier wall BW1 is a barrier wall closest to the display area DA, For example, the first barrier wall BW1 spaces apart the display area DA from all other barrier walls (including the second barrier wall BW2).

The corner region in some embodiments includes a first sub-region RA, in which a pixel definition layer is present, the array substrate includes a plurality of apertures AP extending through the pixel definition layer in the first sub-region RA. The plurality of apertures AP are arranged in a grid-like pattern. The corner region in some embodiments further includes a second sub-region RB, in which layers comprising an organic material (e.g., a polymer material) are removed. For example, in the second sub-region RB, the planarization layer and the pixel definition layer are completely removed.

Referring to FIG. 11, the first sub-region RA is spaced apart from the barrier walls by the second sub-region RB, thus the first sub-region RA is more distal to the barrier walls. Although the grid-like pattern of the pixel definition layer is present in the first sub-region RA, the organic encapsulating sub-layer of the encapsulating layer can planarize the first sub-region RA. Accordingly, the plurality of signal lines can be disposed in the first sub-region RA.

The second sub-region RB is closer to the barrier walls. In one example, the second sub-region RB is substantially free of the plurality of signal lines SL. For example, the plurality of signal lines SL other than a ground line are disposed in the first sub-region RA, and the ground line is disposed in the second sub-region RB. In one example, the signal lines in the first sub-region RA extends along a direction substantially parallel to a boundary between the first sub-region RA and the second sub-region RB.

In the related array substrate, one or more inter-barrier regions IBR are substantially free of signal lines. For example, in the corner region depicted in FIG. 11, the one or more inter-barrier regions IBR is completely absent of any signal lines. In the side region depicted in FIG. 10, one or more signal lines partially or entirely cross over one or more barrier walls. However, none of the signal lines at least partially extends in the inter-barrier region along a direction substantially parallel to the one or more barrier walls.

As discussed above, the fanout connecting line in the display area technology greatly reduces the size of the bottom bezel (e.g., including the side region and the corner regions). The layout of the signal lines (e.g., touch signal lines) in related array substrate is no longer suitable for the array substrate adopting the fanout connecting line in the display area technology. The inventors of the present disclosure discover a novel and unique structure of the array substrate that effectively disposes the signal lines in a more limited space with a more complex layout in the narrow bezel region.

Accordingly, the present disclosure provides, inter alia, an array substrate and a display apparatus that substantially obviate one or more of the problems due to limitations and disadvantages of the related art. In one aspect, the present disclosure provides an array substrate. In some embodiments, the array substrate includes one or more barrier walls and a plurality of signal lines in a peripheral area. Optionally, the peripheral area includes an inner region, an outer region, and one or more inter-barrier regions. Optionally, the inner region is between a display area and a barrier wall closest to the display area. Optionally, a respective one of the one or more inter-barrier regions is between two adjacent barrier walls. Optionally, the outer region is on a side of a barrier wall most distal to the display area away from the display area. Optionally, the plurality of signal lines comprise one or more first signal lines extending in at least one of the one or more inter-barrier region along a direction substantially parallel to at least one barrier wall.

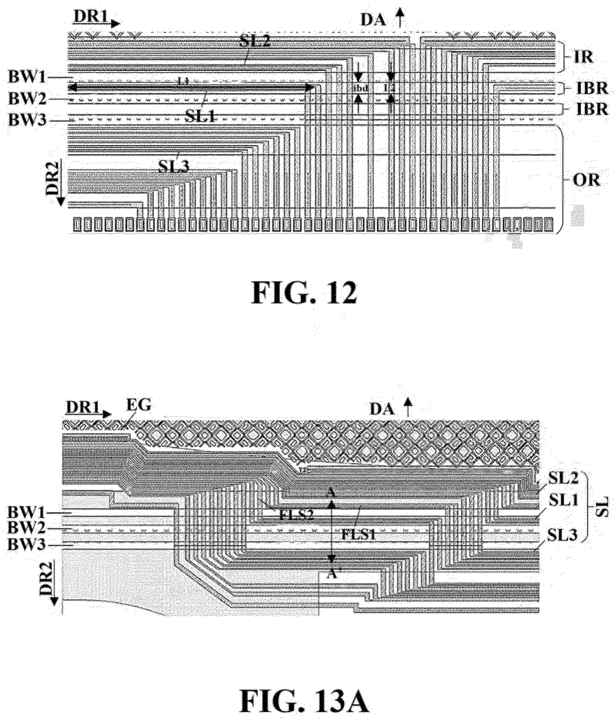

FIG. 12 is a diagram illustrating a layout of signal lines in a peripheral area in an array substrate in some embodiments according to the present disclosure. FIG. 12 may depict the layout of the plurality of signal lines SL in the side region SR (in the bottom bezel region) depicted in FIG. 9. Referring to FIG. 12, the array substrate in some embodiments includes one or more barrier walls (e.g., a first barrier wall BW1, a second barrier wall BW2, and a third barrier wall BW3). The peripheral area of the array substrate in some embodiments includes an inner region IR, an outer region OR, and one or more inter-barrier regions IBR. The inner region IR is between the display area DA and a barrier wall (e.g., the first barrier wall BW1) closest to the display area DA. A respective one of the one or more inter-barrier regions IBR may correspond to a region between the first area EA1 and the second area EA2 depicted in FIG. 8. The outer region OR is on a side of a barrier wall most distal to the display area DA away from the display area DA. In one example, the outer region OR is between the barrier wall most distal to the display area DA and an integrated circuit connected to signal lines in the peripheral area.

In some embodiments, the array substrate includes one or more first signal lines SL1, a plurality of second signal lines SL2, and a plurality of third signal lines SL3 in the peripheral area. In some embodiments, the one or more first signal lines SL1, the plurality of second signal lines SL2, and the plurality of third signal lines SL3 include touch signal lines connected to a touch control integrated circuit.

In some embodiments, the one or more first signal lines SL1 extend in at least one of the one or more inter-barrier region IBR along a direction substantially parallel to at least one barrier wall. In some embodiments, a respective first signal line of the one or more first signal lines SL1 includes a first portion and a second portion connected to each other. The first portion extends in at least one of the one or more inter-barrier region IBR along a direction substantially parallel to at least one barrier wall. In one example depicted in FIG. 12, the first portion extends in an inter-barrier region between the first barrier wall BW1 and the second barrier wall BW2. The first portion extends along a direction substantially parallel to the first barrier wall BW1, the second barrier wall BW2, and the third barrier wall BW3. The second portion crosses over at least one barrier wall. In one example, the second portion crosses over the second barrier wall BW2 and the third barrier wall BW3. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

In some embodiments, a length L1 of the first portion extending in the at least one of the one or more inter-barrier region IBR is at least 1.5 times of (e.g., at least 2.0 times of, at least 2.5 time of, at least 3.0 times of, at least 3.5 time of, at least 4.0 times of, at least 4.5 time of, at least 5.0 times of, at least 5.5 time of, at least 6.0 times of, at least 6.5 time of, at least 7.0 times of, at least 7.5 time of, at least 8.0 times of, at least 8.5 time of, at least 9.0 times of, at least 9.5 time of, at least 10.0 times of) a respective inter-barrier distance ibd of a respective inter-barrier region of the one or more inter-barrier region IBR. As used herein, the term “inter-barrier distance” refers to a shortest distance between two adjacent barrier walls. In one example, the inter-barrier distance is a distance along a second direction DR2. In one example, the first direction DR1 and the second direction DR2 intersect each other. In another example, the second direction DR2 is a direction from the display area DA to the peripheral area. In another example, the first direction DR1 is substantially parallel to a boundary between the display area DA and the peripheral area.

In some embodiments, an orthographic projection of the first portion on a base substrate is substantially non-overlapping with (e.g., at least 80% non-overlapping with, at least 85% non-overlapping with, at least 90% non-overlapping with, at least 95% non-overlapping with, at least 98% non-overlapping with, at least 99% non-overlapping with, or completely non-overlapping with) an orthographic projection of any barrier wall on the base substrate. In some embodiments, an orthographic projection of the second portion on the base substrate at least partially overlaps with an orthographic projection of at least one barrier wall on the base substrate.

In some embodiments, the one or more first signal lines SL1 are absent in the inner region IR.

In some embodiments, the plurality of second signal lines SL2 extend at least partially in the inner region IR, and at least partially cross over the one or more inter-barrier regions IBR. Optionally, the plurality of second signal lines SL2 at least partially cross over the outer region OR. In some embodiments, a total length L2 of a portion of a respective second signal line of the plurality of second signal lines SL2 in a respective inter-barrier region of the one or more inter-barrier regions IBR is in a range of 1.0 time to 1.5 times (e.g., 1.0 time to 1.1 times, 1.1 times to 1.2 times, 1.2 times to 1.3 times, 1.3 times to 1.4 times, or 1.4 times to 1.5 times) of a respective inter-barrier distance ibd of a respective inter-barrier region of the one or more inter-barrier region IBR.

In some embodiments, the portion of the respective second signal line of the plurality of second signal lines SL2 in the respective inter-barrier region of the one or more inter-barrier regions IBR extends along a direction non-parallel to the one or more barrier walls. Optionally, the portion of the respective second signal line of the plurality of second signal lines SL2 in the respective inter-barrier region of the one or more inter-barrier regions IBR extends along the second direction DR2.

In some embodiments, a respective second signal line of the plurality of second signal lines SL2 includes a third portion and a fourth portion connected to each other. The third portion extends in the inner region IR along a direction substantially parallel to at least one barrier wall. In one example depicted in FIG. 12, the third portion extends along a direction substantially parallel to the first barrier wall BW1, the second barrier wall BW2, and the third barrier wall BW3. The fourth portion crosses over at least one barrier wall. In one example, the fourth portion crosses over the first barrier wall BW1, the second barrier wall BW2, and the third barrier wall BW3.

In some embodiments, an orthographic projection of the third portion on a base substrate is substantially non-overlapping with (e.g., at least 80% non-overlapping with, at least 85% non-overlapping with, at least 90% non-overlapping with, at least 95% non-overlapping with, at least 98% non-overlapping with, at least 99% non-overlapping with, or completely non-overlapping with) an orthographic projection of any barrier wall on the base substrate. In some embodiments, an orthographic projection of the fourth portion on the base substrate at least partially overlaps with an orthographic projection of at least one barrier wall on the base substrate.

In some embodiments, a respective third signal line of the plurality of third signal lines SL3 includes a fifth portion and a sixth portion connected to each other. The fifth portion and the sixth portion extend in the outer region OR. The fifth portion extends along a direction substantially parallel to at least one barrier wall. In one example depicted in FIG. 12, the fifth portion extends along a direction substantially parallel to the first barrier wall BW1, the second barrier wall BW2, and the third barrier wall BW3. The sixth portion extends along a direction substantially parallel to the second direction DR2.

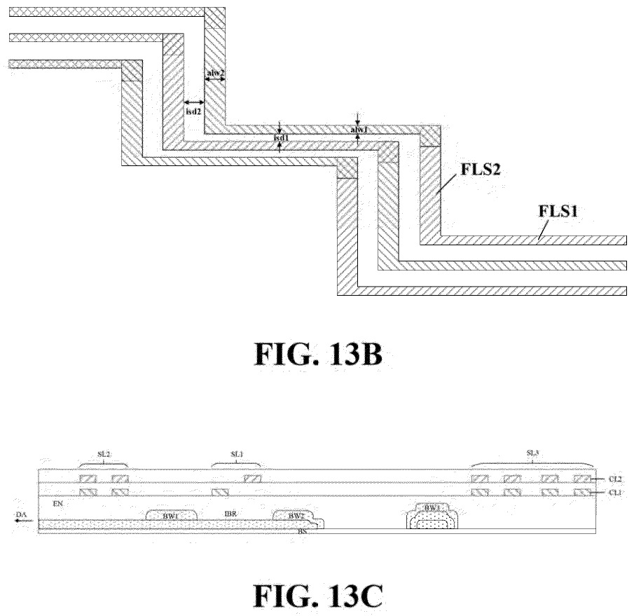

FIG. 13A is a diagram illustrating a layout of signal lines in a peripheral area in an array substrate in some embodiments according to the present disclosure. FIG. 13A may depict the layout of the plurality of signal lines transitioning from the side region SR to a corner region (e.g., the first corner region CR1) depicted in FIG. 9. To conform to the shape of an edge of the display area DA in this region, the plurality of signal lines SL have a stepped pattern. As used herein, the term “stepped pattern” refers to that a respective signal line includes first line segments FLS1 and second line segments FLS2 alternately connected together, the first line segments FLS1 and the second line segments FLS2 extending along different directions, and the second line segments FLS2 extending toward the display area DA. Optionally, the first line segments FLS1 extend along a direction substantially parallel to the first direction DR1, The inventors of the present disclosure discover that by having the stepped pattern, the array substrate having the fanout connecting line in the display area technology can sufficiently accommodate the layout of the signal lines in the bottom bezel.

In one example, the second line segments FLS2 extend toward the display area DA along a uniform direction.

In an alternative example, the second line segments FLS2 extend toward the display area DA along at least two different directions but all toward the display area DA. For example, one or more second line segments extend along the second direction DR2, and another one or more second line segments extend along a direction at an angle of 15 degrees with respect to the second direction DR2.

In some embodiments, the stepped pattern includes at least three steps. In one example, a respective signal line of the plurality of signal lines SL includes at least three second line segments.

FIG. 13B is a diagram illustrating a layout of first line segments and second line segments in some embodiments according to the present disclosure. Referring to FIG. 13B, in some embodiments, the first line segments FLS1 have a first average line width alw1, and the second line segments FLS2 have a second average line width alw2. The second average line width alw2 is greater than the first average line width alw1. Optionally, the first average line width alw1 is in a range of 1 μm to 5 μm (e.g., 1 μm to 2 μm, 2 μm to 3 μm, 3 μm to 4 μm, or 4 μm to 5 μm), and the second average line width alw2 is in a range of 5 μm to 25 μm (e.g., 5 μm to 10 μm, 10 μm to 15 μm, 15 μm to 20 μm, or 20 μm to 25 μm). In one example, the first average line width alw1 is about 3.2 μm, the second average line width alw2 is about 14 μm.

In some embodiments, the first line segments FLS1 are spaced apart from each other by a first inter-segment distance isd1, and the second line segments FLS2 are spaced apart from each other by a second inter-segment distance isd2. The second inter-segment distance isd2 is greater than the first inter-segment distance isd1. Optionally, the first inter-segment distance isd1 is in a range of 2 μm to 6 μm (e.g., 2 μm to 3 μm, 3 μm to 4 μm, 4 μm to 5 μm, or 5 μm to 6 μm), and the second inter-segment distance isd2 is in a range of 10 μm to 26 μm (e.g., 10 μm to 15 μm, 15 μm to 20 μm, or 20 μm to 26 μm), In one example, the first inter-segment distance isd1 is about 4 μm, the second inter-segment distance isd2 is about 18 μm.

In some embodiments, the array substrate includes a pixel definition layer in the display area DA, and the pixel definition layer is at least partially absent in the peripheral area. In some embodiments, the plurality of signal lines SL is spaced apart from an edge of the pixel definition layer by a distance no more than 100 μm, e.g., no more than 90 am, no more than 80 μm, no more than 70 μm, no more than 60 μm, no more than 50 μm, no more than 40 μm, no more than 30 μm, or no more than 20 μm. In one example, referring to FIG. 13A, the plurality of signal lines SL is spaced apart from the edge EG of the pixel definition layer by a distance of 20 μm.

FIG. 13C is a cross-sectional view along an A-A′ line in FIG. 13A. Referring to FIG. 13C, the array substrate in some embodiments includes a base substrate BS; a first barrier wall BW1, a second barrier wall BW2, and a third barrier wall BW3 on the base substrate BS; at least one sub-layer of an encapsulating layer EN on a side of the first barrier wall BW1, the second barrier wall BW2, and the third barrier wall BW3 away from the base substrate BS; and one or more first signal lines SL1, a plurality of second signal lines SL2, and a plurality of third signal lines SL3 on a side of the encapsulating layer EN away from the base substrate BS. Optionally, a first adjacent signal line of the one or more first signal lines includes, in an inter-barrier region IBR, a first single segment in a first conductive layer CL1 but absent in a second conductive layer CL2, and a second single segment in the second conductive layer CL2 but absent in the first conductive layer CL1. Optionally, the array substrate includes a first inorganic encapsulating sub-layer and a second inorganic encapsulating sub-layer (e.g., CVD1 and CVD2 denoted in FIG. 1 or FIG. 2) on a side of the first barrier wall BW1, the second barrier wall BW2, and the third barrier wall BW3 away from the base substrate BS. Optionally, the first inorganic encapsulating sub-layer and the second inorganic encapsulating sub-layer conform to the shape of each barrier wall. For example, a slope angle of a respective barrier wall is substantially the same or similar to a slope angle of the first inorganic encapsulating sub-layer and a slope angle of the second inorganic encapsulating sub-layer on the respective barrier wall.

In some embodiments, a respective second signal line of the plurality of second signal lines SL2 includes two segments in the first conductive layer CL1 and the second conductive layer CL2, respectively. Optionally, a respective third signal line of the plurality of third signal lines SL3 includes two segments in the first conductive layer CL1 and the second conductive layer CL2, respectively. In one example, the first conductive layer CL1 is the first touch metal layer ML1 denoted in FIG. 1 or FIG. 2. In another example, the second conductive layer CL2 is the second touch metal layer ML2 denoted in FIG. 1 or FIG. 2.

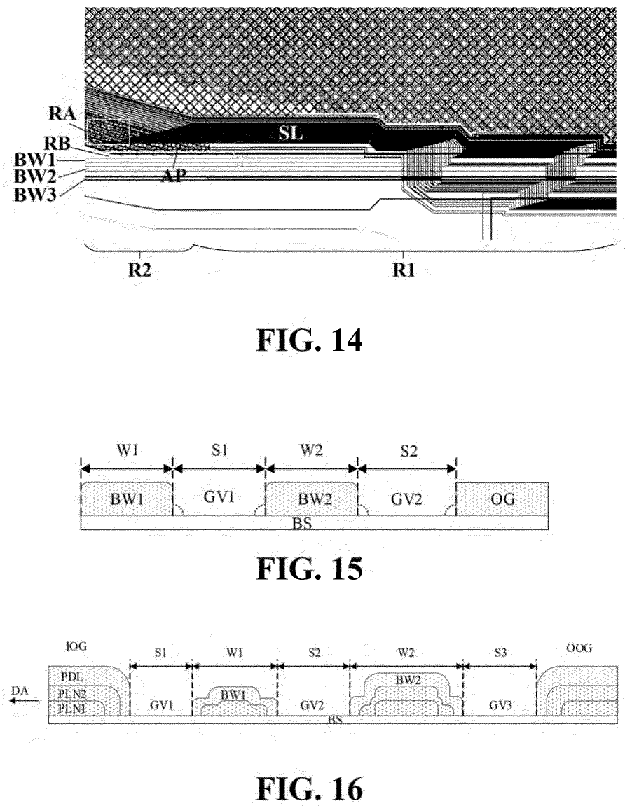

FIG. 14 is a diagram illustrating a layout of signal lines in a peripheral area in an array substrate in some embodiments according to the present disclosure. FIG. 14 depicts a layout of signal lines in a first region R1 and a second region R2. The first region R1 corresponds to a region depicted in FIG. 12, e.g., a region transitioning from the side region SR to a corner region (e.g., the first corner region CR1) depicted in FIG. 9. The second region R2 corresponds to a corner region (e.g., the first corner region CR1) depicted in FIG. 9.

The corner region in some embodiments includes a first sub-region RA, in which a pixel definition layer is present, the array substrate includes a plurality of apertures AP extending through the pixel definition layer in the first sub-region RA. The plurality of apertures AP are arranged in a grid-like pattern. The corner region in some embodiments further includes a second sub-region RB, in which layers comprising an organic material (e.g., a polymer material) are removed. For example, in the second sub-region RB, the planarization layer and the pixel definition layer are completely removed.

Referring to FIG. 14, the first sub-region RA is spaced apart from the barrier walls by the second sub-region RB, thus the first sub-region RA is more distal to the barrier walls. Although the grid-like pattern of the pixel definition layer is present in the first sub-region RA, the organic encapsulating sub-layer of the encapsulating layer can planarize the first sub-region RA. Accordingly, the plurality of signal lines can be disposed in the first sub-region RA.

The second sub-region RB is closer to the barrier walls. In one example, the second sub-region RB is substantially free of the plurality of signal lines SL. For example, the plurality of signal lines SL other than a ground line are disposed in the first sub-region RA, and the ground line is disposed in the second sub-region RB. In one example, the signal lines in the first sub-region RA extends along a direction substantially parallel to a boundary between the first sub-region RA and the second sub-region RB.

FIG. 15 is a cross-sectional view of a portion of an array substrate in some embodiments according to the present disclosure. Referring to FIG. 15, the array substrate in some embodiments includes a first barrier wall BW1 and a second barrier wall BW2 spaced apart from each other. The array substrate further includes a first groove GV1 spacing apart the first barrier wall BW1 and the second barrier wall BW2. Optionally, the array substrate further includes an organic material layer OG, and a second groove GV2 spacing apart the second barrier wall BW2 and the organic material layer OG. The inventors of the present disclosure discover that, when the first barrier wall BW1, the second barrier wall BW2, or the organic material layer OG has a relatively large segment difference with respect to a base substrate BS, the array substrate is prone to residual material deposition at a corner region of a groove (e.g., the region denoted by dotted lines), particularly when the groove is relatively narrow. When the residual material is a metallic or conductive material, the array substrate is prone to short between adjacent signal lines.

The inventors of the present disclosure discover that the residual material deposition can be obviated if a width of the groove between two adjacent barrier walls is greater than a sum of wall widths of two barrier walls adjacent to the groove, particularly when the barrier wall has a relatively large segment difference with respect to the base substrate BS. For example, a first groove width S1 is greater than a sum of a first wall width W1 of the first barrier wall BW1 and a second wall width W2 of the second barrier wall BW2. As used herein, the term “wall width” refers to a width of a barrier wall along a plane intersecting the barrier walls, the grooves, and the organic material layer OG and perpendicular to a surface of the base substrate BS; the term “groove width” refers to a width of a groove along the plane intersecting the barrier walls, the grooves, and the organic material layer OG and perpendicular to a surface of the base substrate BS.

The inventors of the present disclosure further discover that the residual material deposition can be obviated if a width between a barrier wall and an organic material layer is greater than twice of a wall width of the barrier wall, particularly when a width of the organic material layer OG is far greater than the wall width of the barrier wall. For example, a second groove width S2 is greater than twice of a second wall width W2 of the second barrier wall BW2.

FIG. 16 is a cross-sectional view of a portion of an array substrate in some embodiments according to the present disclosure, Referring to FIG. 16, the array substrate in some embodiments includes, sequentially arranged, an inner organic material layer IOG, a first groove GV1, a first barrier wall BW1, a second groove GV2, a second barrier wall BW2, a third groove GV3, and an outer organic material layer OOG, in a peripheral area of the array substrate. Optionally, the inner organic material layer IOG includes one or more insulating material layer from the display area DA. In one example, the inner organic material layer IOG includes a first planarization layer PLN1, a second planarization layer PLN2, and a pixel definition layer PDL. Optionally, a groove corresponds to an inter-barrier region as discussed above.

In some embodiments, the first groove GV1 has a first groove width S1, the second groove GV2 has a second groove width S2, the third groove GV3 has a third groove width S3, the first barrier wall BW1 has a first wall width W1, and the second barrier wall BW2 has a second wall width W2. The first groove GV1 is between the inner organic material layer IOG and the first barrier wall BW1, the second groove GV2 is between the first barrier wall BW1 and the second barrier wall BW2, and the third groove GV3 is between the second barrier wall BW2 and the outer organic material layer OOG.

The first groove width S1 is typically relatively small, for example, less than twice of the first wall width W1. However, typically a slope angle of the inner organic material layer IOG is relatively small, thus a segment difference of the inner organic material layer IOG with respect to the base substrate BS is relatively small. The inventors of the present disclosure discover that, when the region corresponding to the first groove GV1 is planarized, signal lines may be disposed in this region. Optionally, the slope angle of the inner organic material layer IOG is in a range of 5 degrees to 30 degrees, e.g., 5 degrees to 10 degrees, 10 degrees to 15 degrees, 15 degrees to 20 degrees, 20 degrees to 25 degrees, or 25 degrees to 30 degrees. Optionally, the segment difference of the inner organic material layer IOG with respect to the base substrate BS is in a range of 1 μm to 2 μm, e.g., 1.0 μm to 1.5 μm, or 1.5 μm to 2.0 μm.

The second groove width S2 is typically less than a sum of the first wall width W1 and the second wall width W2, e.g., about the same as the first wall width W1 or the second wall width W2. Further, the second barrier wall BW2 typically has a relatively large segment difference with respect to the base substrate BS. The inventors of the present disclosure discover that it is to be avoided to have signal lines disposed in a region corresponding to the second groove GV2.

The third groove width S3 is typically greater than twice of the second wall width W2. Accordingly, the inventors of the present disclosure discover that, when the region corresponding to the third groove GV3 is planarized, signal lines may be disposed in this region.

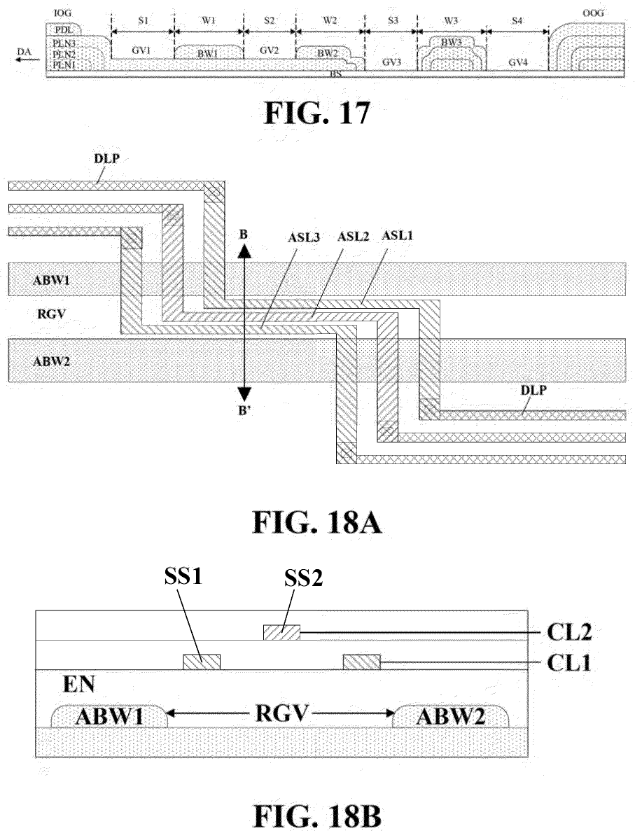

FIG. 17 is a cross-sectional view of a portion of an array substrate in some embodiments according to the present disclosure. Referring to FIG. 17, the array substrate in some embodiments includes, sequentially arranged, an inner organic material layer IOG, a first groove GV1, a first barrier wall BW1, a second groove GV2, a second barrier wall BW2, a third groove GV3, a third barrier wall BW3, a fourth groove GV4, and an outer organic material layer OOG, in a peripheral area of the array substrate. Optionally, the inner organic material layer IOG includes one or more insulating material layer from the display area DA. In one example, the inner organic material layer IOG includes a first planarization layer PLN1, a second planarization layer PLN2, a third planarization layer PLN3, and a pixel definition layer PDL. Optionally, a groove corresponds to an inter-barrier region as discussed above.

In some embodiments, the first groove GV1 has a first groove width S1, the second groove GV2 has a second groove width S2, the third groove GV3 has a third groove width S3, the fourth groove GV4 has a fourth groove width S4, the first barrier wall BW1 has a first wall width W1, the second barrier wall BW2 has a second wall width W2, and the third barrier wall BW3 has a third wall width W3. The first groove GV1 is between the inner organic material layer IOG and the first barrier wall BW1, the second groove GV2 is between the first barrier wall BW1 and the second barrier wall BW2, the third groove GV3 is between the second barrier wall BW2 and the third barrier wall BW3, and the fourth groove GV4 is between the third barrier wall BW3 and the outer organic material layer OOG.

The first groove width S1 is typically relatively small, for example, less than twice of the first wall width W1. However, typically a slope angle of the inner organic material layer IOG is relatively small, thus a segment difference of the inner organic material layer IOG with respect to the base substrate BS is relatively small. The inventors of the present disclosure discover that, when the region corresponding to the first groove GV1 is planarized, signal lines may be disposed in this region. Optionally, the slope angle of the inner organic material layer IOG is in a range of 5 degrees to 30 degrees, e.g., 5 degrees to 10 degrees, 10 degrees to 15 degrees, 15 degrees to 20 degrees, 20 degrees to 25 degrees, or 25 degrees to 30 degrees. Optionally, the segment difference of the inner organic material layer IOG with respect to the base substrate BS is in a range of 1 μm to 2 μm, e.g., 1.0 μm to 1.5 μm, or 1.5 μm to 2.0 μm.

The second groove width S2 is typically less than a sum of the first wall width W1 and the second wall width W2, e.g., about the same as the first wall width W1 or the second wall width W2. In one example, the second groove width S2 is in a range of 35 μm to 40 μm; the first wall width W1 or the second wall width W2 is in a range of 30 μm to 40 μm. However, the first barrier wall BW1 and the second barrier wall BW2 typically have relatively small segment differences with respect to the base substrate BS. In one example, the segment difference of the first barrier wall BW1 or the second barrier wall BW2 with respect to the base substrate BS is in a range of 1 μm to 2 μm, e.g., 1.0 μm to 1.5 μm, or 1.5 μm to 2.0 μm. The inventors of the present disclosure discover that, when the region corresponding to the second groove GV2 is planarized, signal lines may be disposed in this region.

The third groove width S3 is typically less than a sum of the second wall width W2 and the third wall width W3, e.g., about the same as the second wall width W2 or the third wall width W3. Further, the third barrier wall BW3 typically has a relatively large segment difference with respect to the base substrate BS. The inventors of the present disclosure discover that it is to be avoided to have signal lines disposed in a region corresponding to the third groove GV3.

The fourth groove width S4 is typically greater than twice of the third wall width W3. Accordingly, the inventors of the present disclosure discover that, when the region corresponding to the fourth groove GV4 is planarized, signal lines may be disposed in this region.

The inventors of the present disclosure further discover that, in order to dispose signal lines in a region corresponding to a groove that does not sufficient groove width, or a groove having an adjacent barrier wall with a large segment difference with respect to the base substrate, a unique signal line layout may be adopted to achieve disposition of signal line in such an inter-barrier region.

FIG. 18A is a diagram illustrating a layout of signal lines in an inter-barrier region in an array substrate in some embodiments according to the present disclosure, Referring to FIG. 18A, a respective groove RGV is in an inter-barrier region between a first adjacent barrier wall ABW1 and a second adjacent barrier wall ABW2. The array substrate includes a plurality of adjacent signal lines in the inter-barrier region corresponding to the respective groove RGV. In one example, the plurality of adjacent signal lines in the inter-barrier region include a first adjacent signal line ASL1, a second adjacent signal line ASL2, and a third adjacent signal line ASL3 adjacent to each other and sequentially arranged.

In some embodiments, two adjacent signal lines in the inter-barrier region corresponding to the respective groove RGV are in two different layers, respectively. The plurality of signal lines in the inter-barrier region corresponding to the respective groove RGV are alternately in two different layers. In one example, the first adjacent signal line ASL1, the second adjacent signal line ASL2, and the third adjacent signal line ASL3 in the inter-barrier region corresponding to the respective groove RGV are three adjacent touch signal lines. In another example, the first adjacent signal line ASL1, the second adjacent signal line ASL2, and the third adjacent signal line ASL3 in the inter-barrier region corresponding to the respective groove RGV are alternately in a first touch electrode layer and a second touch electrode layer.

The two adjacent signal lines in the inter-barrier region corresponding to the respective groove RGV may be disposed in any two appropriate layers, respectively. For example, the two adjacent signal lines in the inter-barrier region corresponding to the respective groove RGV may be disposed in any two different layers selected from a first touch electrode layer, a second touch electrode layer, a first signal line layer, a second signal line layer, and a third gate metal layer.

A portion of a respective signal line of the plurality of signal lines on a side of an adjacent barrier wall away from the respective groove RGV may be a portion having two layers, e.g., a portion having a first segment in the first touch electrode layer and a second segment in the second touch electrode layer. Referring to FIG. 18A, the respective signal line of the plurality of signal lines in some embodiments includes a double-layer portion DLP having a first segment in the first touch electrode layer and a second segment in the second touch electrode layer. The double-layer portion DLP is connected to a portion of the respective signal line in the inter-barrier region corresponding to the respective groove RGV through a via.

In some embodiments, to obviate RC delay issue due to the layer difference between adjacent signal lines, the respective signal line of the plurality of signal lines includes at least a first single segment in a first conductive layer but absent in a second conductive layer and a second single segment in the second conductive layer but absent in the first conductive layer.

In some embodiments, a total length of first single segment(s) and a total length of second single segment(s) in the respective signal line are substantially the same. As used herein, the term “substantially the same” refers to a difference between two values not exceeding 10% of a base value (e.g., one of the two values), e.g., not exceeding 8%, not exceeding 6%, not exceeding 4%, not exceeding 2%, not exceeding 1%, not exceeding 0.5%, not exceeding 0.1%, not exceeding 0.05%, and not exceeding 0.01%, of the base value.

FIG. 18B is a cross-sectional view along a B-B′ line in FIG. 18A. Referring to FIG. 18B, in some embodiments, in the inter-barrier region corresponding to the respective groove RGV, one or more first single segments SS1 and one or more second single segments SS2 respectively from adjacent signal lines are alternately arranged.

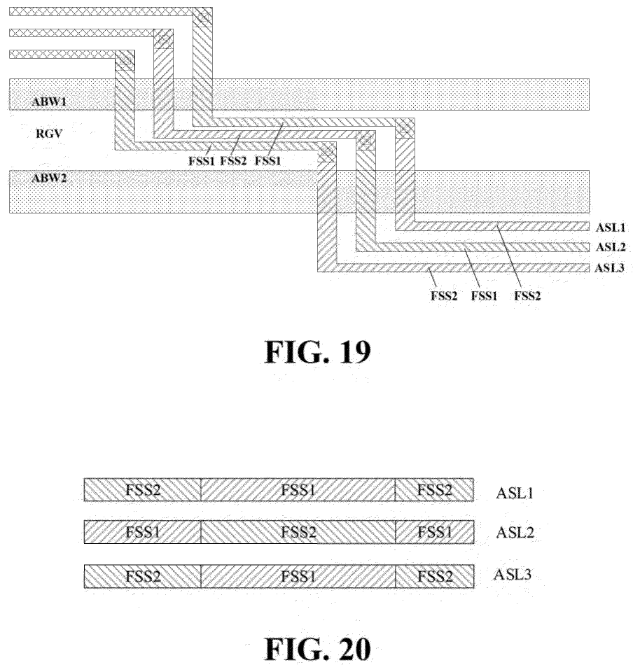

FIG. 19 is a diagram illustrating a layout of signal lines in an inter-barrier region in an array substrate in some embodiments according to the present disclosure, Referring to FIG. 19, a first adjacent signal line ASL1 includes at least a first single segment FSS1 in a first conductive layer but absent in a second conductive layer and a second single segment FSS2 in the second conductive layer but absent in the first conductive layer. The first single segment FSS1 is at least partially in the inter-barrier region corresponding to the respective groove RGV. The second single segment FSS2 is at least partially outside the inter-barrier region corresponding to the respective groove RGV.

The second adjacent signal line ASL2 includes at least a first single segment FSS1 in a first conductive layer but absent in a second conductive layer and a second single segment FSS2 in the second conductive layer but absent in the first conductive layer. The first single segment FSS1 is at least partially outside the inter-barrier region corresponding to the respective groove RGV. The second single segment FSS2 is at least partially in the inter-barrier region corresponding to the respective groove RGV.

The third adjacent signal line ASL3 includes at least a first single segment FSS1 in a first conductive layer but absent in a second conductive layer and a second single segment FSS2 in the second conductive layer but absent in the first conductive layer. The first single segment FSS1 is at least partially in the inter-barrier region corresponding to the respective groove RGV. The second single segment FSS2 is at least partially outside the inter-barrier region corresponding to the respective groove RGV.

In some embodiments, in the inter-barrier region corresponding to the respective groove RGV, first single segments and second single segment(s) are alternately arranged.

In some embodiments, in at least one region outside the inter-barrier region corresponding to the respective groove RGV, first single segments and second single segment(s) are alternately arranged.

With respect to the first adjacent signal line ASL1, a total length of the first single segment and a total length of the second single segment in the first adjacent signal line ASL1 are substantially the same.

With respect to the second adjacent signal line ASL2, a total length of the first single segment and a total length of the second single segment in the second adjacent signal line ASL2 are substantially the same.

With respect to the third adjacent signal line ASL3, a total length of the first single segment and a total length of the second single segment in the third adjacent signal line ASL3 are substantially the same.

Referring to FIG. 19, in some embodiments, the first single segment FSS1 and the second single segment FSS2 of the respective signal line are connected to each other through a via in the inter-barrier region corresponding to the respective groove RGV.

FIG. 20 is a diagram illustrating a layout of signal lines in an inter-barrier region in an array substrate in some embodiments according to the present disclosure, Referring to FIG. 20, the respective signal line includes at least three single segments in two different layers. For example, the first adjacent signal line ASL1 includes a first single segment FSS1 connecting two adjacent second single segment. The second adjacent signal line ASL2 includes a second single segment FSS2 connecting two adjacent first single segment. The third adjacent signal line ASL3 includes a first single segment FSS1 connecting two adjacent second single segment.

In some embodiments, a total length of first single segment(s) and a total length of second single segment(s) in the respective signal line are substantially the same. For example, a total length of the first single segment FSS1 of the first adjacent signal line ASL1 is substantially the same as a total length of two adjacent second single segment of the first adjacent signal line ASL1. A total length of the second single segment FSS2 of the second adjacent signal line ASL2 is substantially the same as a total length of two adjacent first single segment of the second adjacent signal line ASL2. A total length of the first single segment FSS1 of the third adjacent signal line ASL3 is substantially the same as a total length of two adjacent second single segment of the third adjacent signal line ASL3. The inventors of the present disclosure discover that this intricate structure can obviate the RC delay in the signal lines.

In some embodiments, a sum of lengths of single segments in a first adjacent signal line is substantially the same as a sum of lengths of single segments in a second adjacent signal line. Optionally, the plurality of signal lines have a substantially the same total lengths of single segments.

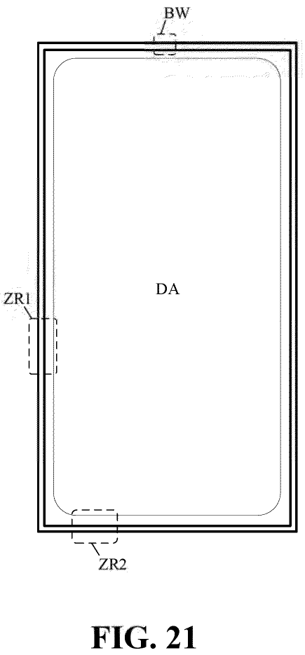

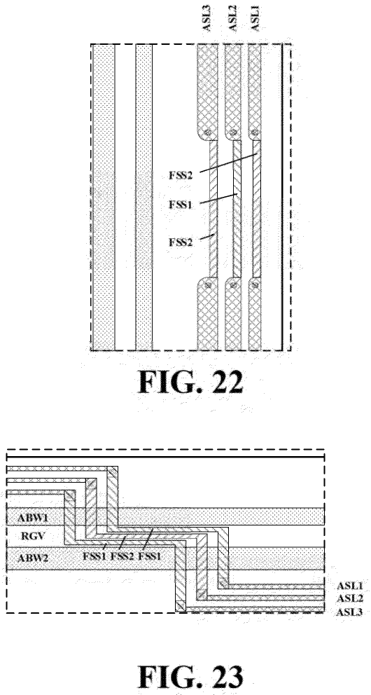

FIG. 21 is a diagram illustrating the structure of an array substrate in some embodiments according to the present disclosure. FIG. 22 is a diagram illustrating a layout of signal lines in a first zoom-in region in the array substrate depicted in FIG. 21. FIG. 23 is a diagram illustrating a layout of signal lines in a second zoom-in region in the array substrate depicted in FIG. 21. Referring to FIG. 21 to FIG. 23, first single segment(s) and second single segment(s) of a same respective signal line may be disposed in different regions. In one example, the first single segment(s) and the second single segment(s) of the same respective signal line may be disposed in the first sub-area PA1 and the third sub-area PA3 as depicted in FIG. 9.

For example, the first adjacent signal line ASL1 includes a first single segment FSS1 in the first sub-area PA1 and a second single segment FSS2 in the third sub-area PA3. A total length of the first single segment FSS1 in the first sub-area PA1 is substantially the same as a total length of the second single segment FSS2 in the third sub-area PA3.

The second adjacent signal line ASL2 includes a second single segment FSS2 in the first sub-area PA1 and a first single segment FSS1 in the third sub-area PA3. A total length of the second single segment FSS2 in the first sub-area PA1 is substantially the same as a total length of the first single segment FSS1 in the third sub-area PA3.

The third adjacent signal line ASL3 includes a first single segment FSS1 in the first sub-area PA1 and a second single segment FSS2 in the third sub-area PA3. A total length of the first single segment FSS1 in the first sub-area PA1 is substantially the same as a total length of the second single segment FSS2 in the third sub-area PA3.

In some embodiments, the array substrate includes a display area and a peripheral area. Optionally, the array substrate in the peripheral area includes a first organic structure (e.g., the inner organic material layer IOG or the outer organic material layer OOG in FIG. 15 to FIG. 17), one or more barrier walls (e.g., the first barrier wall BW1, the second barrier wall BW2, or the third barrier wall BW3 in FIG. 15 to FIG. 17), and a second organic structure (e.g., the inner organic material layer IOG or the outer organic material layer OOG in FIG. 15 to FIG. 17) sequentially arranged along a direction away from the display area. Optionally, referring to FIG. 15 to FIG. 17, a respective barrier wall of the one or more barrier walls include one or more organic insulating layers. Optionally, the respective barrier wall spaces apart two adjacent grooves extending at least partially into the one or more organic insulating layers. Optionally, the two adjacent grooves are on two sides of the respective barrier wall along the direction along which the first organic structure, the one or more barrier walls, and the second organic structure are sequentially arranged. Optionally, referring to FIG. 13A to FIG. 13C, and FIG. 15 to FIG. 17; the array substrate further includes a plurality of signal lines SL in the peripheral area. Optionally, at least one signal line of the plurality of signal lines extends along a direction substantially parallel to the one or more barrier walls in a region having a groove adjacent to a barrier wall.

In some embodiments, the one or more barrier walls include two adjacent barrier walls (e.g., any two of the first barrier wall BW1, the second barrier wall BW2, and the third barrier wall BW3 in FIG. 15 to FIG. 17), Optionally, the array substrate further includes a groove (e.g., any one of the first groove GV1, the second groove GV2, or the third groove GV3) spacing apart the two adjacent barrier walls. Optionally, one or more signal lines are present in an inter-barrier region corresponding to a groove where a width of the groove between the two adjacent barrier walls is greater than a sum of wall widths of two barrier walls adjacent to the groove.

In some embodiments, the array substrate further includes an organic structure (e.g., the inner organic material layer IOG or the outer organic material layer OOG in FIG. 15 to FIG. 17) adjacent to a barrier wall (e.g., the first barrier wall BW), the second barrier wall BW2, or the third barrier wall BW3 in FIG. 15 to FIG. 17), and a groove spacing apart the organic structure and the barrier wall. Optionally, one or more signal lines are present in a region corresponding to the groove where a width between the barrier wall and the organic structure is greater than twice of a wall width of the barrier wall.

In some embodiments, a groove (e.g., any one of the first groove GV1, the second groove GV2, or the third groove GV3) is adjacent to a barrier wall or an organic structure having a slope angle in a range of 5 degrees to 30 degrees. Optionally, a width of the groove, when the groove is between the two adjacent barrier walls, is equal to or less than a sum of wall widths of the two adjacent barrier walls, or, when the groove is between a barrier wall and an organic structure, is equal to or less than twice of a wall width of the barrier wall; and at least one signal line of the plurality of signal lines extends along a direction substantially parallel to the one or more barrier walls in a region having the groove adjacent to the barrier wall or the organic structure having the slope angle in the range of 5 degrees to 30 degrees.

In some embodiments, a groove (e.g., any one of the first groove GV1, the second groove GV2, or the third groove GV3) is adjacent to a barrier wall or an organic structure having a thickness in a range of 1 μm to 2 μm. Optionally, a width of the groove, when the groove is between the two adjacent barrier walls, is equal to or less than a sum of wall widths of the two adjacent barrier walls, or, when the groove is between a barrier wall and an organic structure, is equal to or less than twice of a wall width of the barrier wall; and at least one signal line of the plurality of signal lines extends along a direction substantially parallel to the one or more barrier walls in a region having the groove adjacent to the barrier wall or the organic structure having the thickness in the range of 1 μm to 2 μm

In some embodiments, a groove (e.g., any one of the first groove GV1, the second groove GV2, or the third groove GV3) is adjacent to a barrier wall or an organic structure having a slope angle greater than 30 degrees or having a thickness greater than 2 μm. Optionally, a width of the groove, when the groove is between the two adjacent barrier walls, is equal to or less than a sum of wall widths of the two adjacent barrier walls, or, when the groove is between a barrier wall and an organic structure, is equal to or less than twice of a wall width of the barrier wall; and none of the plurality of signal lines extends along a direction substantially parallel to the one or more barrier walls in a region having the groove adjacent to the barrier wall or the organic structure having the slope angle greater than 30 degrees or having the thickness greater than 2 μm.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus. Optionally, the display apparatus is a quantum dots display apparatus.

In some embodiments, the display apparatus includes a plurality of light emitting elements on the base substrate; an encapsulating layer on a side of the plurality of light emitting elements away from the base substrate; a first touch metal layer on a side of the encapsulating layer away from the base substrate; a touch insulating layer on a side of the first touch metal layer away from the base substrate; and a second touch metal layer on a side of the touch insulating layer away from the base substrate. Optionally, the plurality of signal lines are a plurality of touch control signal lines.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising one or more barrier walls and a plurality of signal lines in a peripheral area and on a side of the one or more barrier walls away from a base substrate;
wherein the peripheral area comprises an inner region, an outer region, and one or more inter-barrier regions;
the inner region is between a display area and a barrier wall closest to the display area;
a respective one of the one or more inter-barrier regions is between two adjacent barrier walls;
the outer region is on a side of a barrier wall most distal to the display area away from the display area; and
the plurality of signal lines comprise one or more first signal lines extending in at least one of the one or more inter-barrier region along a direction substantially parallel to at least one barrier wall.

2. The array substrate of claim 1, wherein a respective first signal line of the one or more first signal lines comprises a first portion and a second portion connected to each other;
the first portion extends in at least one of the one or more inter-barrier regions along a direction substantially parallel to at least one barrier wall; and
the second portion crosses over at least one barrier wall.

3. The array substrate of claim 2, wherein a length of the first portion extending in the at least one of the one or more inter-barrier region is at least 1.5 times of a respective inter-barrier distance of a respective inter-barrier region of the one or more inter-barrier regions.

4. The array substrate of claim 2, wherein an orthographic projection of the first portion on the base substrate is substantially non-overlapping with an orthographic projection of any barrier wall on the base substrate; and
an orthographic projection of the second portion on the base substrate at least partially overlaps with an orthographic projection of at least one barrier wall on the base substrate.

5. The array substrate of claim 1, wherein the plurality of signal lines further comprise a plurality of second signal lines extending at least partially in the inner region, and at least partially crossing over the one or more inter-barrier regions; and
a portion of a respective second signal line of the plurality of second signal lines in a respective inter-barrier region of the one or more inter-barrier regions extends along a direction non-parallel to the one or more barrier walls.

6. The array substrate of claim 5, wherein a total length of the portion of the respective second signal line of the plurality of second signal lines in the respective inter-barrier region is in a range of 1.0 time to 1.5 times of a respective inter-barrier distance of a respective inter-barrier region of the one or more inter-barrier region.

7. The array substrate of claim 5, wherein a respective second signal line of the plurality of second signal lines comprises a third portion and a fourth portion connected to each other;
the third portion extends in the inner region along a direction substantially parallel to at least one barrier wall; and
the fourth portion crosses over at least one barrier wall.

8. The array substrate of claim 1, wherein the plurality of signal lines further comprise a plurality of third signal lines extending in the outer region;
a respective third signal line of the plurality of third signal lines comprises a fifth portion and a sixth portion connected to each other;
the fifth portion extends along a direction substantially parallel to at least one barrier wall; and
the sixth portion extends along a direction non-parallel to the one or more barrier walls.

9. The array substrate of claim 1, wherein, in a region transitioning from a side region to a corner region of the peripheral area in a bottom bezel, the plurality of signal lines have a stepped pattern; and
a respective signal line comprises first line segments and second line segments alternately connected together, the first line segments and the second line segments extending along different directions, and the second line segments extending toward the display area.

10. The array substrate of claim 9, wherein the first line segments have a first average line width, the second line segments have a second average line width, the second average line width is greater than the first average line width; and
the first line segments are spaced apart from each other by a first inter-segment distance, the second line segments are spaced apart from each other by a second inter-segment distance, the second inter-segment distance is greater than the first inter-segment distance.

11. The array substrate of claim 1, further comprising a pixel definition layer in the display area;
wherein the pixel definition layer is at least partially absent in the peripheral area; and
the plurality of signal lines is spaced apart from an edge of the pixel definition layer by a distance no more than 100 μm.

12. The array substrate of claim 11, wherein the peripheral area comprises a corner region;
the corner region comprises a first sub-region in which a pixel definition layer is present, and a second sub-region in which layers comprising an organic material are removed;
the array substrate comprises a plurality of apertures arranged in a grid-like pattern and extending through the pixel definition layer in the first sub-region;
the first sub-region is spaced apart from the barrier walls by the second sub-region; and
the second sub-region is substantially free of the plurality of signal lines.

13. The array substrate of claim 1, wherein the one or more barrier walls comprise two adjacent barrier walls;
the array substrate further comprises a groove spacing apart the two adjacent barrier walls; and
one or more signal lines are present in an inter-barrier region corresponding to a groove where a width of the groove between the two adjacent barrier walls is greater than a sum of wall widths of two barrier walls adjacent to the groove.

14. The array substrate of claim 1, further comprising an organic material layer adjacent to a barrier wall, and a groove spacing apart the organic material layer and the barrier wall;
wherein one or more signal lines are present in a region corresponding to the groove where a width between the barrier wall and the organic material layer is greater than twice of a wall width of the barrier wall.

15. The array substrate of claim 1, wherein the one or more barrier walls comprise a first adjacent barrier wall and a second adjacent barrier wall;
wherein the array substrate further comprises:
a respective groove in an inter-barrier region between the first adjacent barrier wall and the second adjacent barrier wall; and
a plurality of adjacent signal lines in the inter-barrier region corresponding to the respective groove; and
wherein the plurality of adjacent signal lines in the inter-barrier region corresponding to the respective groove are alternately in two different layers.

16. The array substrate of claim 15, wherein a portion of a respective adjacent signal line of the plurality of adjacent signal lines on a side of an adjacent barrier wall away from the respective groove comprises a double-layer portion having a first segment in a first conductive layer and a second segment in a second conductive layer; and
the double-layer portion is connected to a portion of the respective adjacent signal line in the inter-barrier region corresponding to the respective groove.

17. The array substrate of claim 15, wherein a respective adjacent signal line of the plurality of adjacent signal lines comprises at least a first single segment in a first conductive layer but absent in a second conductive layer, and a second single segment in the second conductive layer but absent in the first conductive layer; and
in the inter-barrier region corresponding to the respective groove, one or more first single segments and one or more second single segments respectively from adjacent signal lines are alternately arranged.

18. The array substrate of claim 17, wherein a total length of first single segment(s) and a total length of second single segment(s) in the respective adjacent signal line are substantially the same; and
the plurality of signal lines have a substantially the same total lengths of single segments.

19. (canceled)

20. A display apparatus, comprising the array substrate of claim 1, and one or more integrated circuits connected to the array substrate;
wherein the display apparatus comprises:
a plurality of light emitting elements on the base substrate;
an encapsulating layer on a side of the plurality of light emitting elements away from the base substrate;
a first touch metal layer on a side of the encapsulating layer away from the base substrate;
a touch insulating layer on a side of the first touch metal layer away from the base substrate; and
a second touch metal layer on a side of the touch insulating layer away from the base substrate;
wherein the plurality of signal lines are a plurality of touch control signal lines in at least one of the first touch metal layer or the second touch metal layer.

21. An array substrate, comprising a display area and a peripheral area;
wherein the array substrate in the peripheral area comprises a first organic structure, one or more barrier walls, and a second organic structure sequentially arranged along a direction away from the display area;
wherein a respective barrier wall of the one or more barrier walls comprises one or more organic insulating layers;
wherein the respective barrier wall spaces apart two adjacent grooves extending at least partially into the one or more organic insulating layers; and
the two adjacent grooves are on two sides of the respective barrier wall along the direction along which the first organic structure, the one or more barrier walls, and the second organic structure are sequentially arranged;
wherein the array substrate further comprises a plurality of signal lines in the peripheral area and on a side of the one or more barrier walls away from a base substrate; and
at least one signal line of the plurality of signal lines extends along a direction substantially parallel to the one or more barrier walls in a region having a groove adjacent to a barrier wall.

22. (canceled)

23. (canceled)

24. (canceled)

25. (canceled)

26. (canceled)
